(19) United States
(12) Patent Application Publication
(10) Pub. No.: US 2025/0273503 A1
(43) Pub. Date: Aug. 28, 2025

(54) METHOD FOR MANUFACTURING SEMICONDUCTOR DEVICE, AND ADHESIVE FILM FOR SEMICONDUCTOR WAFER PROCESSING

(71) Applicant: Resonac Corporation, Minato-ku, Tokyo (JP)

(72) Inventors: Koichi CHABANA, Minato-ku, Tokyo (JP); Makoto SATO, Minato-ku, Tokyo (JP); Tsuyoshi TAZAWA, Minato-ku, Tokyo (JP)

(21) Appl. No.: 18/857,814

(22) PCT Filed: Jul. 11, 2023
(86) PCT No.: PCT/JP2023/025614

§ 371 Date: Oct. 18, 2024

(30) Foreign Application Priority Data
Sep. 26, 2022 (JP) 2022-152433

(51) Int. Cl. H01L 21/683; C09J 7/38; H01L 21/78; H01L 23/00

(52) U.S. Cl. CPC H01L 21/6836; C09J 7/38; H01L 21/78; H01L 24/29; H01L 24/83; C09J 2203/326; H01L 2221/68327; H01L 2224/2919; H01L 2224/83191; H01L 2924/3512

(57) ABSTRACT

A method for manufacturing a semiconductor device, including: sticking a stacked body, which includes a backgrind tape including a base material and a pressure-sensitive adhesive layer formed on the base material, and a bonding adhesive layer formed on the pressure-sensitive adhesive layer, onto a semiconductor wafer on a side in which an electrode is provided from the bonding adhesive layer side; grinding the semiconductor wafer to be thin; dicing the thinned semiconductor wafer and the bonding adhesive layer to be singulated into a semiconductor chip with the bonding adhesive layer; and electrically connecting an electrode of the semiconductor chip with the bonding adhesive layer to an electrode of another semiconductor chip or a wiring circuit board, in which the semiconductor wafer and the stacked body have a circular shape in plan view, and in plan view, a diameter A of the semiconductor wafer and a diameter X of the stacked body satisfy a relationship of Expression (1) described below:

$$A - 1.5 mm \leq X < A . \qquad ( 1 )$$

### TECHNICAL FIELD

The present disclosure relates to a method for manufacturing a semiconductor device and an adhesive film for semiconductor wafer processing.

### BACKGROUND ART

Until now, a wire bonding method using a thin metal wire such as a gold wire has been widely applied to connect a semiconductor chip and a substrate. However, in order to respond to demands for a semiconductor device, such as high functionality, high integration, and acceleration, a flip chip connecting method (an FC connecting method) for forming a conductive protrusion referred to as a bump on a semiconductor chip or a substrate to directly connect the semiconductor chip and the substrate has been spread.

As the FC connecting method, a method for performing metal joining using solder, tin, gold, silver, copper, and the like, a method for performing metal joining by applying a supersonic vibration, a method for retaining a mechanical contact by the contraction force of a resin, and the like are known, and from the viewpoint of the reliability of a connecting portion, the method for performing the metal joining using solder, tin, gold, silver, copper, and the like is commonly used.

For example, in the connection between the semiconductor chip and the substrate, a chip on board (COB)-type connecting method, which is frequently used for a ball grid array (BGA), a chip size package (CSP), and the like, is also used as the FC connecting method.

The FC connecting method is also widely used for a chip on chip (COC)-type connecting method for forming a bump or wiring on a semiconductor chip to connect the semiconductor chips (for example, refer to Patent Literature 1).

### CITATION LIST

### Patent Literature

Patent Literature 1: Japanese Unexamined Patent Publication No. 2008-294382

### SUMMARY OF INVENTION

### Technical Problem

In a package required to be further miniaturized, further thinned, and more highly functionalized, a chip stack-type package, a package on package (POP), a through-silicon via (TSV), and the like, in which stacking or multistaging is performed using the connecting method described above, have also begun to be widely spread.

Since it is possible to make the package small by steric arrangement rather than planar arrangement, the technology described above is widely used, is also effective in an improvement in the performance of a semiconductor, a reduction in noise, a reduction in a mounting area, and power saving, and is attracting attention as a next-generation semiconductor wiring technology.

From the viewpoint of improving productivity, a chip on wafer (COW) in which a semiconductor chip is crimped (connected) onto a wafer, and then, is singulated to produce a semiconductor package, and a wafer on wafer (WOW) in which wafers are crimped (connected), and then, are singulated to prepare a semiconductor package are also attracting attention.

In the assembling of the flip chip package described above, first, an adhesive film for semiconductor wafer processing is stuck onto a wafer on a side where an electrode is provided. Next, the wafer is ground on a side opposite to the side where the electrode is provided to make a wafer with an adhesive film for semiconductor wafer processing thin. Next, the thinned wafer with an adhesive film for semiconductor wafer processing is diced to be singulated into a semiconductor chip.

After that, the semiconductor chip is picked up with a collet, and is supplied to a crimping tool via the collet. Next, chip-chip positioning or chip-substrate positioning is performed, and crimping is performed. The temperature of the crimping tool is increased such that metals in upper and lower connecting portions or either one of the upper and lower connecting portions reach a melting point or higher to form metal bonding. In a chip stack PKG in which stacking or multistaging is performed, chip pickup, positioning, and crimping are repeated.

In the flip chip package, the package tends to be miniaturized and thinned, and the semiconductor wafer and the semiconductor chip are required to be further thinned. However, as a thickness required for the semiconductor wafer and the semiconductor chip decreases, the semiconductor wafer is likely to be chipped or cracked during grinding when making the wafer with an adhesive film for semiconductor wafer processing thin. In addition, as the thickness required for the semiconductor wafer and the semiconductor chip decreases, a bonding adhesive layer of the adhesive film for semiconductor wafer processing is likely to be stuck onto a stage of the device when making the wafer with an adhesive film for semiconductor wafer processing thin, and workability decreases.

The present disclosure has been made in consideration of the circumstances described above, and an object thereof is to provide a method for manufacturing a semiconductor device and an adhesive film for semiconductor wafer processing, in which it is possible to prevent a semiconductor wafer from being significantly chipped and cracked during grinding, and prevent a bonding adhesive layer from being stuck onto a stage of a device during grinding.

### Solution to Problem

In order to attain the object described above, the present disclosure provides a method for manufacturing a semiconductor device and an adhesive film for semiconductor wafer processing described below.

[1] A method for manufacturing a semiconductor device, including: a step of preparing a semiconductor wafer including a plurality of electrodes on one of main surfaces to stick a stacked body, which includes a backgrind tape including a base material and a pressure-sensitive adhesive layer formed on the base material, and a bonding adhesive layer formed on the pressure-sensitive adhesive layer, onto the semiconductor wafer on a side in which an electrode is provided from the bonding adhesive layer side; a step of grinding the semiconductor wafer on a side opposite to the side in which the electrode is provided to make the semiconductor wafer thin; a step of dicing the thinned semiconductor wafer and the bonding adhesive layer to be singulated into a semiconductor chip with the bonding adhesive layer; and a step of electrically connecting an electrode of the semiconductor chip with the bonding adhesive layer to an electrode of another semiconductor chip or a wiring circuit board, in which the semiconductor wafer and the stacked body have a circular shape in plan view, and in plan view, a diameter A of the semiconductor wafer and a diameter X of the stacked body satisfy a relationship of Expression (1) described below:

$$A - 1.5 mm \leq X < A . \qquad ( 1 )$$

[2] The method for manufacturing a semiconductor device according to [1] described above, in which a bonding adhesive force between the pressure-sensitive adhesive layer and the bonding adhesive layer is lower than a bonding adhesive force between the bonding adhesive layer and the semiconductor wafer.

[3] An adhesive film for semiconductor wafer processing, including a stacked body, which includes a backgrind tape including a base material and a pressure-sensitive adhesive layer formed on the base material, and a bonding adhesive layer formed on the pressure-sensitive adhesive layer, in which the semiconductor wafer and the stacked body have a circular shape in plan view, and in plan view, a diameter A of the semiconductor wafer and a diameter X of the stacked body satisfy a relationship of Expression (1) described below:

$$A - 1.5 mm \leq X < A . \qquad ( 1 )$$

### Advantageous Effects of Invention

According to the present disclosure, it is possible to provide the method for manufacturing a semiconductor device and the adhesive film for semiconductor wafer processing, in which it is possible to prevent the semiconductor wafer from being significantly chipped and cracked during grinding, and prevent the bonding adhesive layer from being stuck onto the stage of the device during grinding.

### BRIEF DESCRIPTION OF DRAWINGS

FIG. 1 is a schematic cross sectional view illustrating one embodiment of an adhesive film for semiconductor wafer processing according to the present disclosure.

FIG. 2 is a plan view illustrating one embodiment of the adhesive film for semiconductor wafer processing according to the present disclosure.

### DESCRIPTION OF EMBODIMENTS

Hereinafter, in some cases, a preferred embodiment of the present disclosure will be described in detail, with reference to the drawings. However, the present disclosure is not limited to the following embodiment. Note that in the drawings, the same reference numerals will be applied to the same or corresponding parts, and the repeated description will be omitted. In addition, a positional relationship such as the top, bottom, right, and left is based on a positional relationship illustrated in the drawings, unless otherwise specified. Further, a dimensional ratio in the drawings is not limited to that illustrated.

### <Adhesive Film for Semiconductor Wafer Processing>

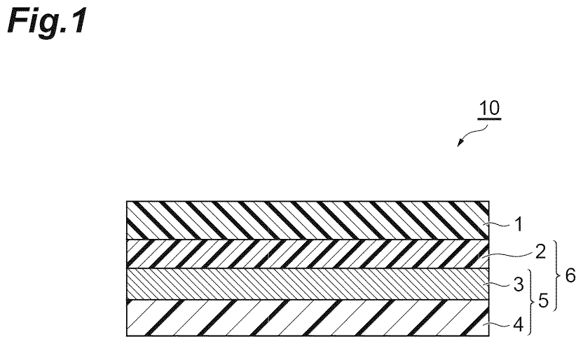

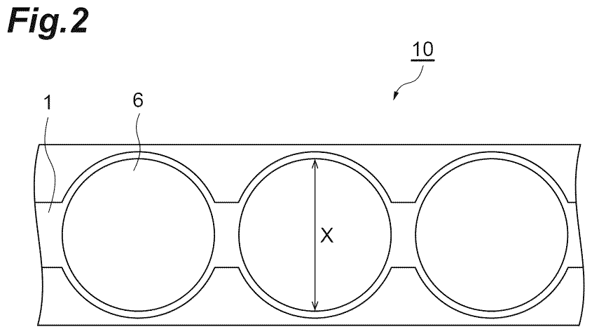

FIG. 1 is a schematic cross sectional view illustrating one embodiment of an adhesive film for semiconductor wafer processing (hereinafter, also simply referred to as an “adhesive film”) of the present disclosure. FIG. 2 is a plan view illustrating one embodiment of the adhesive film for semiconductor wafer processing of the present disclosure. An adhesive film 10 for semiconductor wafer processing illustrated in FIG. 1 and FIG. 2 is composed of a base material film 1 and a stacked body 6. The stacked body 6 is composed of a bonding adhesive layer 2 and a backgrind tape 5. The backgrind tape 5 is composed of a pressure-sensitive adhesive layer 3 and a base material 4.

In the adhesive film 10 of this embodiment, as illustrated in FIG. 2, the stacked body 6 is precut to have a circular shape in plan view, in accordance with the shape of a semiconductor wafer to be stuck. In a method for manufacturing a semiconductor device, the stacked body 6 is peeled from the base material film 1, and is stuck onto the main surface of the semiconductor wafer having a circular shape in plan view on a side where an electrode is provided. Here, the circular shape may be an approximately circular shape, and includes not only a true circle but also a circle close to a true circle, and a circle having a positioning notch (an orientation flat).

In addition, in the adhesive film 10 of this embodiment, in plan view, a diameter A (Unit: mm) of the semiconductor wafer to be stuck and a diameter (a precut diameter) X (Unit: mm) of the stacked body 6 satisfy the relationship of Expression (1) described below:

$$A - 1.5 mm \leq X < A . \qquad ( 1 )$$

By the diameter X of the stacked body 6 satisfying Expression (1) described above, it is possible to prevent the semiconductor wafer from being significantly chipped and cracked during grinding, and prevent the bonding adhesive layer 2 from being stuck onto a stage of a device during grinding. Here, in a case where X is less than A-1.5 mm, a wide region in the end portion of the main surface (the sticking surface) of the wafer onto which the stacked body 6 is stuck is exposed without being covered with the stacked body 6. In this case, the end portion of the wafer is likely to be significantly (for example, a size of 2 mm or more) chipped or cracked. In contrast, by setting X to be A-1.5 mm or more, it is possible to reduce the exposed region in the end portion of the sticking surface, and prevent the wafer from being significantly chipped or cracked. From the viewpoint of more sufficiently obtaining such an effect, X may be A-1.0 mm or more. On the other hand, in a case where X is greater than A, the end portion of the stacked body 6 protrudes from the sticking surface of the wafer, and the bonding adhesive layer 2 of the stacked body 6 is likely to be stuck onto the stage of the device. In addition, in a case where X is the same as A, only by slight misalignment of the sticking position of the stacked body 6 with respect to the wafer, the end portion of the stacked body 6 protrudes from the sticking surface of the wafer, and the bonding adhesive layer 2 of the stacked body 6 is likely to be stuck onto the stage of the device. In contrast, by setting X to be less than A, it is possible to prevent the end portion of the stacked body 6 from protruding from the sticking surface of the wafer, and prevent the bonding adhesive layer 2 of the stacked body 6 from being stuck onto the stage of the device. From the viewpoint of more sufficiently obtaining such an effect, X may be A-0.5 mm or less.

Hereinafter, each layer configuring the adhesive film 10 of this embodiment will be described in detail.

### (Bonding Adhesive Layer 2)

The bonding adhesive layer can be configured by using a bonding adhesive composition. Even though there is no particular limitation, hereinafter, the bonding adhesive composition configuring the bonding adhesive layer will be described.

The bonding adhesive composition, for example, contains a resin (a) having a weight average molecular weight of less than 10000 (hereinafter, referred to as a “component (a)” in some cases), and a curing agent (b) (hereinafter, referred to as a “component (b)” in some cases). The bonding adhesive composition, as necessary, may contain a

polymer component (c) having a weight average molecular weight of 10000 or more (hereinafter, referred to as a “component (c)” in some cases). The bonding adhesive composition, as necessary, may contain a fluxing agent (d) (hereinafter, referred to as a “component (d)” in some cases). The bonding adhesive composition, as necessary, may contain a filler (e) (hereinafter, referred to as a “component (e)” in some cases).

Component (a): Resin Having Weight Average Molecular Weight of Less Than 10000

The component (a) is not particularly limited, but a component that reacts with a curing agent is preferable. Since a component having a small molecular weight may be decomposed when heated and cause voids, the component that reacts with the curing agent is preferable from the viewpoint of heat resistance.

Examples of the component (a) include an epoxy resin, an acrylic resin, and the like.

The epoxy resin is not particularly limited insofar as the epoxy resin has two or more epoxy groups in the molecules, and for example, bisphenol A-type, bisphenol F-type, naphthalene-type, phenol novolac-type, cresol novolac-type, phenol aralkyl-type, biphenyl-type, triphenyl methane-type, dicyclopentadiene-type, and various polyfunctional epoxy resins can be used. Only one type of such epoxy resins can be used alone, or two or more types thereof can be used as a mixture.

The content of the epoxy resin, for example, is 10 to 50% by mass, on the basis of the total solid content of the bonding adhesive composition. In a case where the content is 10% by mass or more, there is a sufficient amount of curing component, and the fluxion of the resin can be sufficiently controlled even after curing, and in a case where the content is 50% by mass or less, there is a tendency that a cured product is not excessively hardened, and the warpage of a package can be reduced.

Note that in this specification, the “solid content” indicates a non-volatile content excluding a volatile substance (water, a solvent, or the like) contained in the bonding adhesive composition, and also includes a component that is in the form of a liquid, syrup, or wax at a room temperature (in the vicinity of 25° C.′).

It is preferable that the epoxy resin is in the form of a solid at a room temperature (25° C.). In the case of the epoxy resin in the form of a solid, voids are less likely to occur, and the tackiness of the bonding adhesive composition before curing (in a stage B) is low, which leads to excellent handleability, compared to an epoxy resin in the form of a liquid.

The acrylic resin is not particularly limited insofar as the acrylic resin has one or more acrylic groups in the molecules, and for example, bisphenol A-type, bisphenol F-type, naphthalene-type, phenol novolac-type, cresol novolac-type, phenol aralkyl-type, biphenyl-type, triphenyl methane-type, dicyclopentadiene-type, fluorene-type, adamantane-type, and various polyfunctional acrylic resins can be used. Only one type of such acrylic resins can be used alone, or two or more types thereof can be used as a mixture.

The content of the acrylic resin is preferably 10 to 50% by mass, and more preferably 15 to 40% by mass, on the basis of the total solid content of the bonding adhesive composition. In a case where the content is 10% by mass or more, there is a sufficient amount of curing component, and the fluxion of the resin can be sufficiently controlled even after curing, and in a case where the amount is 50% by mass or less, there is a tendency that the cured product is not excessively hardened, and the warpage of the package can be reduced.

It is preferable that the acrylic resin is in the form of a solid at a room temperature (25° C.). In the case of the acrylic resin in the form of a solid, the voids are less likely to occur, and the tackiness of the bonding adhesive composition before curing (in the stage B) is low, which leads to excellent handleability, compared to an acrylic resin in the form of a liquid.

It is preferable that the number of functional groups of the acrylic group is 3 or less in the acrylic resin. In a case where the number of functional groups is 3 or less, there is a tendency that the number of functional groups does not excessively increase, curing easily proceeds in a short period of time, and a curing reaction rate is easily improved. It is considered that this is because it is possible to suppress the remaining of unreacted groups due to rapid progress of a curing network caused by an excessive increase in the number of functional groups.

### Component (b): Curing Agent

Examples of the component (b) include a phenol resin-based curing agent, an acid anhydride-based curing agent, an amine-based curing agent, an imidazole-based curing agent, a phosphine-based curing agent, an azo compound, an organic peroxide, and the like.

### (i) Phenol Resin-Based Curing Agent

The phenol resin-based curing agent is not particularly limited insofar as the phenol resin-based curing agent has two or more phenolic hydroxyl groups in the molecules, and for example, a phenol novolac resin, a cresol novolac resin, a phenol aralkyl resin, a cresol naphthol formaldehyde polycondensate, a triphenyl methane-type polyfunctional phenol resin, and various polyfunctional phenol resins can be used. Only one type of such phenol resin-based curing agents can be used alone, or two or more types thereof can be used as a mixture.

An equivalence ratio (Phenolic Hydroxyl Group/Epoxy Group or Acrylic Group, a molar ratio) of the phenol resin-based curing agent to the component (a), from the viewpoint of excellent curability, bonding adhesiveness, and preservation stability, is preferably 0.3 to 1.5, more preferably 0.4 to 1.0, and even more preferably 0.5 to 1.0. In a case where the equivalence ratio is 0.3 or more, there is a tendency that the curability is improved, and a bonding adhesive force is improved, in a case where the equivalence ratio is 1.5 or less, there is a tendency that no excessive unreacted phenolic hydroxyl groups remain, the coefficient of water absorption is kept low, and insulation reliability is improved.

### (ii) Acid Anhydride-Based Curing Agent

As the acid anhydride-based curing agent, for example, a methyl cyclohexane tetracarboxylic dianhydride, a trimellitic anhydride, a pyromellitic anhydride, a benzophenone tetracarboxylic dianhydride, and ethylene glycol bisanhydrotrimellitate can be used. Only one type of such acid anhydride-based curing agents can be used alone, or two or more types thereof can be used as a mixture.

An equivalence ratio (Acid Anhydride Group/Epoxy Group or Acrylic Group, a molar ratio) of the acid anhydride-based curing agent to the component (a), from the viewpoint of excellent curability, bonding adhesiveness, and preservation stability, is preferably 0.3 to 1.5, more preferably 0.4 to 1.0, and even more preferably 0.5 to 1.0. In a case where the equivalence ratio is 0.3 or more, there is a tendency that the curability is improved, and the bonding adhesive force is improved, and in a case where the equivalence ratio is 1.5 or less, there is a tendency that no excessive unreacted acid anhydrides remain, the coefficient of water absorption is kept low, and the insulation reliability is improved.

(iii) Amine-Based Curing Agent

As the amine-based curing agent, for example, dicyan diamide can be used.

An equivalence ratio (Amine/Epoxy Group or Acrylic Group, a molar ratio) of the amine-based curing agent to the component (a), from the viewpoint of excellent curability, bonding adhesiveness, and preservation stability, is preferably 0.3 to 1.5, more preferably 0.4 to 1.0, and even more preferably 0.5 to 1.0. In a case where the equivalence ratio is 0.3 or more, there is a tendency that the curability is improved, and the bonding adhesive force is improved, and in a case where the equivalence ratio is 1.5 or less, there is a tendency that no excessive unreacted amines remain, and the insulation reliability is improved.

### (iv) Imidazole-Based Curing Agent

Examples of the imidazole-based curing agent include 2-phenyl imidazole, 2-phenyl-4-methyl imidazole, 1-benzyl-2-methyl imidazole, 1-benzyl-2-phenyl imidazole, 1-cyanoethyl-2-undecyl imidazole, 1-cyano-2-phenyl imidazole, 1-cyanoethyl-2-undecyl imidazole trimellitate, 1-cyanoethyl-2-phenyl imidazolium trimellitate, 2,4-diamino-6-[2′-methyl imidazolyl-(1′)]-ethyl-s-triazine, 2,4-diamino-6-[2′-undecyl imidazolyl-(1′)]-ethyl-s-triazine, 2,4-diamino-6-[2′-ethyl-4′-methyl imidazolyl-(1′)]-ethyl-s-triazine, a 2,4-diamino-6-[2′-methyl imidazolyl-(1′)]-ethyl-s-triazine isocyanuric acid adduct, a 2-phenyl imidazole isocyanuric acid adduct, 2-phenyl-4,5-dihydroxymethyl imidazole, 2-phenyl-4-methyl-5-hydroxymethyl imidazole, and adducts of epoxy resins and imidazoles. Among them, from the viewpoint of excellent curability, preservation stability, and connection reliability, the 1-cyanoethyl-2-undecyl imidazole, the 1-cyano-2-phenyl imidazole, the 1-cyanoethyl-2-undecyl imidazole trimellitate, the 1-cyanoethyl-2-phenyl imidazolium trimellitate, the 2,4-diamino-6-[2′-methyl imidazolyl-(1′)]-ethyl-s-triazine, the 2,4-diamino-6-[2′-ethyl-4′-methyl imidazolyl-(1′)]-ethyl-s-triazine, the 2,4-diamino-6-[2′-methyl imidazolyl-(1′)]-ethyl-s-triazine isocyanuric acid adduct, the 2-phenyl imidazole isocyanuric acid adduct, the 2-phenyl-4,5-dihydroxymethyl imidazole, and the 2-phenyl-4-methyl-5-hydroxymethyl imidazole are preferable. Only one type of such imidazole-based curing agents can be used alone, or two or more types thereof can be used in combination. In addition, a latent curing agent in which such imidazole-based curing agents are microencapsulated can also be used.

The content of the imidazole-based curing agent is preferably 0.1 to 20 parts by mass, and more preferably 0.1 to 10 parts by mass, with respect to 100 parts by mass of the component (a). In a case where the content of the imidazole-based curing agent is 0.1 parts by mass or more, there is a tendency that the curability is improved, and in a case where the content is 20 parts by mass or less, there is a tendency that the bonding adhesive layer is not cured before metal joining is formed, and a connection failure is less likely to occur.

### (v) Phosphine-Based Curing Agent

Examples of the phosphine-based curing agent include triphenyl phosphine, tetraphenyl phosphonium tetraphenyl borate, tetraphenyl phosphonium tetra(4-methyl phenyl) borate, and tetraphenyl phosphonium (4-fluorophenyl) borate. Only one type of such phosphine-based curing agents can be used alone, or two or more types thereof can be used in combination.

The content of the phosphine-based curing agent is preferably 0.1 to 10 parts by mass, and more preferably 0.1 to 5 parts by mass, with respect to 100 parts by mass of the component (a). In a case where the content of the phosphine-based curing agent is 0.1 parts by mass or more, there is a tendency that the curability is improved, and in a case where the content is 10 parts by mass or less, there is a tendency that the bonding adhesive layer is not cured before the metal joining is formed, and the connection failure is less likely to occur.

Only one type of each of the phenol resin-based curing agent, the acid anhydride-based curing agent, and the amine-based curing agent can be used alone, or two or more types thereof can be used as a mixture. Only one type of each of the imidazole-based curing agent and the phosphine-based curing agent may be used alone, and the phenol resin-based curing agent, the acid anhydride-based curing agent, or the amine-based curing agent may be used together.

### (vi) Organic Peroxide

Examples of the organic peroxide include ketone peroxide, peroxyketal, hydroperoxide, dialkyl peroxide, diacyl peroxide, peroxydicarbonate, peroxyester, and the like. From the viewpoint of the preservation stability, the hydroperoxide, the dialkyl peroxide, and the peroxyester are preferable. Further, from the viewpoint of the heat resistance, the hydroperoxide and the dialkyl peroxide are preferable. Only one type of such organic peroxides can be used alone, or two or more types thereof can be used in combination.

The content of the organic peroxide is preferably 0.5 to 10 parts by mass, and more preferably 1 to 5 parts by mass, with respect to 100 parts by mass of the component (a). In a case where the content of the organic peroxide is 0.5 parts by mass or more, curing is likely to sufficiently proceed, and in a case where the content is 10 parts by mass or less, there is a tendency that curing rapidly proceeds and the number of reaction points increases, which makes a molecular chain shorter, or a decrease in reliability due to the remaining of the unreacted groups can be suppressed.

A combination of the component (a) and the curing agents (i) to (vi) is not particularly limited insofar as curing proceeds, and from the viewpoint of the handleability, the preservation stability, and the curability, the epoxy resin may be phenol and imidazole, an acid anhydride and imidazole, amine and imidazole, or imidazole alone. Since the productivity is improved in a case where connection is attained in a short period of time, the epoxy resin may be the imidazole alone, which is excellent in quick curability. Since a volatile content such as a low-molecular-weight component can be suppressed in a case where curing is attained in a short period of time, it is also possible to suppress the occurrence of voids. From the viewpoint of the handleability and the preservation stability, the acrylic resin may be an organic peroxide.

The curing reaction rate may be 80% or more, or 90% or more. In a case where the curing reaction rate at 200° C.′ (a solder melting temperature or lower)/5 s is 80% or more, there is a tendency that solder is less likely to flow or scatter during connection (at the solder melting temperature or higher), and the connection failure and poor insulation reliability are less likely to occur.

A curing system may be a radical polymerization system. For example, as a resin having a weight average molecular weight of 10000 or less, a radical polymerization-type acrylic resin (an acryl-peroxide curing system) is preferable, compared to an anionic polymerization-type epoxy resin (an epoxy-curing agent curing system). Since the acryl-curing system (the radical polymerization system) has a higher curing reaction rate, voids are more easily suppressed, and metals in a connecting portion are more easily prevented from flowing or scattering. In the case of containing the anionic polymerization-type epoxy resin or the like, it may be difficult for the curing reaction rate to be 80% or more. In the case of using the epoxy resin together, the epoxy resin may be 20 parts by mass or less with respect to 80 parts by mass of the acrylic resin. The acryl-curing system may be used alone.

### Component (c): Polymer Component Having Weight Average Molecular Weight of 10000 or More

Examples of the component (c) include an epoxy resin, a phenoxy resin, a polyimide resin, a polyamide resin, a polycarbodiimide resin, a cyanate ester resin, an acrylic resin, a polyester resin, a polyethylene resin, a polyether sulfone resin, a polyether imide resin, a polyvinyl acetal resin, a urethane resin, acrylic rubber, and the like. The component (c), from the viewpoint of being excellent in the heat resistance and film formability, may be the epoxy resin, the phenoxy resin, the polyimide resin, the acrylic resin, the acrylic rubber, the cyanate ester resin, the polycarbodiimide resin, or the like, and from the viewpoint of being more excellent in the heat resistance and the film formability, may be the epoxy resin, the phenoxy resin, the polyimide resin, the acrylic resin, or the acrylic rubber. Only one type of such polymer components can be used alone, or two or more types thereof can be used as a mixture or a copolymer.

A mass ratio of the component (c) and the epoxy resin that is the component (a) is not particularly limited, and from the viewpoint of retaining the shape of a film, the epoxy resin may be 0.01 to 5 parts by mass, 0.05 to 4 parts by mass, or 0.1 to 3 parts by mass, with respect to 1 part by mass of the component (c). In a case where the amount of epoxy resin with respect to 1 part by mass of the component (c) is 0.01 parts by mass or more, there is a tendency that the curability is improved, and the bonding adhesive force is improved, and in a case where the amount is 5 parts by mass or less, there is a tendency that the film formability is improved.

A mass ratio of the component (c) and the acrylic resin that is the component (a) is not particularly limited, and the acrylic resin may be 0.01 to 10 parts by mass, 0.05 to 5 parts by mass, or 0.1 to 5 parts by mass, with respect to 1 part by mass of the component (c). In a case where the amount of acrylic resin with respect to 1 part by mass of the component (c) is 0.01 parts by mass or more, there is a tendency that the curability is improved, and the bonding adhesive force is improved, and in a case where the amount is 10 parts by mass or less, there is a tendency that the film formability is improved.

The glass transition temperature (Tg) of the component (c), from the viewpoint of being excellent in the stickability of the bonding adhesive layer with respect to a substrate and a semiconductor chip, may be 120° C. or lower, 100° C. or lower, or 85° C. or lower. In a case where Tg is 120° C. or lower, there is a tendency that irregularities such as a bump formed on the semiconductor chip, and an electrode and a wiring pattern formed on the substrate are easily embedded in the bonding adhesive layer, and the occurrence of voids due to the remaining of air bubbles is easily suppressed. Note that Tg described above is Tg when measured by using DSC (for example, manufactured by PerkinElmer Inc., product name: “DSC-7 Type”), in a condition of the amount of sample of 10 mg, a temperature increase rate of 10° C./minute, and a measurement atmosphere of air.

The weight average molecular weight of the component (c) is 10000 or more in terms of polystyrene, and in order to exhibit excellent film formability by oneself, may be 30000 or more, 40000 or more, or 50000 or more. In a case where the weight average molecular weight is 10000 or more, there is a tendency that the film formability is improved. Note that in this specification, the weight average molecular weight indicates a weight average molecular weight when measured in terms of polystyrene by using high-performance liquid chromatography (for example, manufactured by SHIMADZU CORPORATION, product name: “C-R4A”).

### Component (d): Fluxing Agent

The bonding adhesive composition may contain a fluxing agent, that is, a flux activating agent that is a compound indicating flux activity (activity of removing an oxide and impurities). Examples of the component (d) include a nitrogen-containing compound having an unshared electron pair, such as imidazoles and amines, carboxylic acids, phenols, and alcohols. Note that in the case of an organic acid such as carboxylic acids, flux activity is highly exhibited, and connectivity is improved, compared to alcohols.

### Component (e): Filler

The bonding adhesive composition may contain a filler in order to control the viscosity and the physical property of the cured product, and in order to suppress the occurrence of voids when connecting the semiconductor chips or the semiconductor chip and the substrate and suppress the coefficient of moisture absorption.

Examples of the component (e) include an inorganic filler, a whisker, a resin filler, and the like. The inorganic filler is an insulating inorganic filler. Only one type of such components (e) may be used alone, or two or more types thereof may be used as a mixture. The shape, the particle size, and the blending amount of the component (e) are not particularly limited.

Examples of the insulating inorganic filler include a filler consisting of glass, silica, alumina, titanium oxide, carbon black, mica, boron nitride, and the like. Among them, the silica, the alumina, the titanium oxide, the boron nitride, and the like are preferable, and the silica, the alumina, and the boron nitride are more preferable.

Examples of the whisker include a whisker consisting of aluminum borate, aluminum titanate, zinc oxide, calcium silicate, magnesium sulfate, boron nitride, and the like.

Examples of the resin filler include a filler consisting of a polyurethane resin, a polyimide resin, a methyl methacrylate resin, a methyl methacrylate-butadiene-styrene copolymerization resin (MBS), and the like.

The component (e), from the viewpoint of improving dispersibility and the bonding adhesive force, may be a surface-treated filler. Examples of a surface treatment include glycidyl-based (epoxy-based), amine-based, phenyl-based, phenyl amino-based, acrylic, methacrylic, vinylic, and silane-based surface treatments. The physical property of the component (e) may be suitably adjusted by the surface treatment.

From the viewpoint of ease of the surface treatment, the component (e) may be a filler subjected to the silane-based surface treatment. Examples of the silane-based surface treatment include epoxy silane-based, aminosilane-based, and acryl silane-based surface treatments.

From the viewpoint of the dispersibility, fluidity, and the bonding adhesive force, the component (e) may be a filler subjected to the glycidyl-based, phenyl amino-based, acrylic, and methacrylic surface treatments. In addition, from the viewpoint of the preservation stability, the component (e) may be a filler subjected to the phenyl-based, acrylic, and methacrylic surface treatments.

For the particle size of the component (e), the average particle size is preferably 1.5 μm or less from the viewpoint of preventing trapping during flip chip connection, and the average particle size is more preferably 1.0 μm or less from the viewpoint of visibility (transparency). Note that the average particle size of the component (e) is a particle size at a point corresponding to a volume of 50% when obtaining a cumulative frequency distribution curve of the particle size with the total volume of the particles as 100%, and can be measured with particle size distribution measurement device using a laser diffraction/scattering method, or the like.

Since the resin filler is capable of imparting flexibility at a high temperature such as 260° C., compared to the inorganic filler, the resin filler is suitable to improve reflow resistance. In addition, since the resin filler is capable of imparting the flexibility, the resin filler is also effective to improve the film formability.

From the viewpoint of the insulation reliability, it is preferable that the component (e) has an insulating property. The bonding adhesive composition may contain a conductive metal filler such as a silver filler and a solder filler.

The content of the component (e) is preferably 30 to 90% by mass, and more preferably 40 to 80% by mass, on the basis of the total solid content of the bonding adhesive composition. In a case where the content of the component (e) is 30% by mass or more, there is a tendency that heat dissipation is high, and the occurrence of voids and the coefficient of moisture absorption can be suppressed. In a case where the content of the component (c) is 90% by mass or less, there is a tendency that a decrease in the fluidity of the bonding adhesive composition and the trapping of the filler into the connecting portion due to an increase in the viscosity can be suppressed, and a decrease in the connection reliability can be suppressed.

The bonding adhesive composition, in addition to the components (a) to (e) described above, may contain additives such as an ion trapper, an antioxidant, a silane coupling agent, a titanium coupling agent, and a leveling agent. Only one type of such additives may be used alone, or two or more types thereof may be used in combination. The content of the additive may be suitably adjusted such that the effect of each of the additives is exhibited.

The bonding adhesive layer 2 can be formed by dissolving or dispersing the bonding adhesive composition containing each of the components described above in a solvent to obtain a varnish, applying the varnish onto the base material film 1, and removing the solvent by heating.

Examples of a method for applying the varnish onto the base material film 1 include a generally known method such as a knife coating method, a roll coating method, a spray coating method, a gravure coating method, a bar coating method, and a curtain coating method.

It is preferable that a temperature condition when removing the solvent by heating is approximately 70 to 150° C.

The solvent to be used is not particularly limited, and it is preferable to determine the solvent in consideration of volatility or the like when forming the bonding adhesive layer, on the basis of a boiling point. Specifically, a solvent having a comparatively low boiling point, such as methanol, ethanol, 2-methoxyethanol, 2-ethoxyethanol, 2-butoxyethanol, methyl ethyl ketone, acetone, methyl isobutyl ketone, toluene, and xylene, is preferable since the curing of the bonding adhesive layer is less likely to proceed when forming the bonding adhesive layer. In addition, in order to improve coatability, a solvent having a comparatively high boiling point, such as dimethyl acetamide, dimethyl formamide, N-methyl pyrrolidone, and cyclohexanone, may be used. Only one type of such solvents can be used alone, or two or more types thereof can be used in combination.

The thickness of the bonding adhesive layer 2 may be 2 to 50 μm, or may be 5 to 20 μm, and from the viewpoint of preventing the resin from protruding after mounting, may be 5 to 16 μm.

### (Base Material Film 1)

The base material film is not particularly limited insofar as the base material film has heat resistance, capable of withstanding a heating condition when drying an organic solvent. Examples of the base material film include a polyolefin film such as a polypropylene film and a polymethyl pentene film, a polyester film such as a polyethylene terephthalate film and a polyethylene naphthalate film, a polyimide film, a polyether imide film, and the like. The base material film may be a single-layer film including only one type of such base material films, or may be a multilayer film including two or more types of such base material films in combination.

### (Backgrind Tape 5)

The backgrind tape 5 including the base material 4 and the pressure-sensitive adhesive layer 3 formed on the base material 4 can be configured by using a known backgrind tape used when grinding the semiconductor wafer. Hereinafter, the backgrind tape will be described, but is not particularly limited.

The base material 4 is not particularly limited, and a known base material can be used. As the base material 4, for example, a resin film is preferable. As the resin film, for example, a polyethylene terephthalate film, a polyethylene naphthalate film, a polybutylene terephthalate film, a polypropylene film, a polyimide film, a polyether imide film, a polyphenylene sulfide film, a polyarylate film, and the like can be used. As the base material 4, the polyester-based film is preferable, and the polyethylene terephthalate film is more preferable.

The thickness of the base material 4 can be suitably selected in a range not impairing the workability. The thickness of the base material 4 may be 200 μm or less, 10 to 150 μm, or 20 to 100 μm.

The pressure-sensitive adhesive layer 3 is not particularly limited, and a known pressure-sensitive adhesive layer can be used. As the pressure-sensitive adhesive layer 3, at least one type selected from the group consisting of a compound having a diol group, an isocyanate compound, a urethane (meth)acrylate compound, a diamine compound, a urea methacrylate compound, and a high-energy-ray-polymerizable copolymer having an ethylenically unsaturated group on a side chain can be used. The pressure-sensitive adhesive layer 3 is preferably composed of a component of which the pressure-sensitive adhesiveness is less likely to be changed in accordance with a storage environment such as a temperature, humidity, a storage period, and the presence or absence of oxygen, and is more preferably composed of a component of which the pressure-sensitive adhesiveness is not changed in accordance with the storage environment.

In addition, the pressure-sensitive adhesive layer 3 may contain components cured with a high energy ray such as an ultraviolet ray and a radiant ray, or heat. Among such components, the component cured with the high energy ray is preferable, and the component cured with the ultraviolet ray is more preferable. In a case where the pressure-sensitive adhesive layer 3 contains the components cured with the high energy ray such as the ultraviolet ray and the radiant ray, or the heat, the pressure-sensitive adhesive force of the pressure-sensitive adhesive layer 3 can be decreased by a curing treatment.

The adhesive film 10 can be obtained by sticking the base material film 1 and the bonding adhesive layer 2 onto the backgrind tape 5, and then, precutting the bonding adhesive layer 2 and the backgrind tape 5 to form the stacked body 6. The sticking and the precutting can be performed by a known method.

In the adhesive film 10, it is preferable that a bonding adhesive force between the pressure-sensitive adhesive layer 3 and the bonding adhesive layer 2 is lower than a bonding adhesive force between the bonding adhesive layer 2 and the semiconductor wafer to be stuck. Accordingly, it is easy to peel the backgrind tape 5 from the bonding adhesive layer 2 after grinding the semiconductor wafer.

### (Method for Manufacturing Semiconductor Device)

A method for manufacturing a semiconductor device according to this embodiment includes a step of preparing the semiconductor wafer including a plurality of electrodes on one of the main surfaces to stick the stacked body 6 in the adhesive film 10 for semiconductor wafer processing onto the semiconductor wafer on a side where the electrode is provided from the bonding adhesive layer 2 side, a step of grinding the semiconductor wafer on a side opposite to the side where the electrode is provided to make the semiconductor wafer thin, a step of dicing the thinned semiconductor wafer and the bonding adhesive layer 2 to be singulated into a semiconductor chip with the bonding adhesive layer, and a step of electrically connecting an electrode of the semiconductor chip with the bonding adhesive layer to an electrode of another semiconductor chip or a wiring circuit board. Here, the semiconductor wafer and the stacked body 6 have a circular shape in plan view, and in plan view, the diameter A of the semiconductor wafer and the diameter X of the stacked body 6 satisfy the relationship of Expression (1) described below. The relationship between X and A may be as described in the description of the adhesive film 10 for semiconductor wafer processing.

$$A - 1.5 mm \leq X < A . \qquad ( 1 )$$

The stacked body 6 can be stuck onto the semiconductor wafer, for example, by hot pressing, roll laminating, vacuum laminating, or the like. The thickness of the bonding adhesive layer 2 in the stacked body 6 may be suitably set in accordance with the size of the semiconductor chip or the wiring circuit board, the height of the bump (the electrode), and the like.

The sticking of the stacked body 6 with respect to the semiconductor wafer may be performed by peeling the stacked body 6 from the base material film 1 in the adhesive film 10 for semiconductor wafer processing, and sticking the peeled stacked body 6 onto the semiconductor wafer, or may be performed by preparing the stacked body 6 not including the base material film 1, and directly sticking the stacked body 6 onto the semiconductor wafer.

Next, the semiconductor wafer with the stacked body is ground on a side opposite to the side where the electrode is provided to make the semiconductor wafer thin. The thickness of the semiconductor wafer after thinning may be 30 to 300 μm.

After that, the backgrind tape 5 is peeled from the thinned semiconductor wafer with the bonding adhesive layer. Next, by dicing the semiconductor wafer with the bonding adhesive layer to singulate the semiconductor wafer into the semiconductor chip, the semiconductor chip onto which the bonding adhesive layer is stuck (the semiconductor chip with the bonding adhesive layer) is produced.

After dicing, the semiconductor chip with the bonding adhesive layer is picked up and crimped onto the wiring circuit board. The crimping is performed at a temperature higher than or equal to the melting point of a solder bump by using a crimping machine such as a flip chip bonder to form the metal bonding in the connecting portion. A heating treatment can also be performed by a heat crimper, a reflow furnace, a pressurization oven, or the like. The semiconductor device can be manufactured via the steps described above.

The preferred embodiment of the present disclosure has been described above, but the present disclosure is not limited to the embodiment described above.

### EXAMPLES

Hereinafter, the present disclosure will be described in more detail by Examples, but the present disclosure is not limited to Examples.

Compounds used in each Example and Comparative Example are as follows.

Resin (a) Having Weight Average Molecular Weight of Less Than 10000
(a-1) Triphenol methane skeleton-containing polyfunctional epoxy resin (manufactured by Mitsubishi Chemical Corporation, product name: “EP1032H60”, weight average molecular weight: 800 to 2000)
(a-2) Bisphenol F-type liquid epoxy resin (manufactured by Mitsubishi Chemical Corporation, product name: “YL983U”, weight average molecular weight: approximately 340)

### Curing Agent (b)

2,4-Diamino-6-[2′-methyl imidazolyl-(1′)]-ethyl-s-triazine isocyanuric acid adduct (manufactured by SHIKOKU CHEMICALS CORPORATION, product name: “2MAOK-PW”)

Polymer Component (c) Having Weight Average Molecular Weight of 10000 or More

Phenoxy resin (manufactured by Tohto Kasei Co., Ltd., product name: “ZX1356”, Tg: approximately 71° C., weight average molecular weight: approximately 63000)

### Fluxing Agent (d) (Carboxylic Acid)

Glutaric acid (melting point: approximately 95° C.)

### Filler (e)

(e-1) Silica filler (manufactured by ADMATECHS COMPANY LIMITED, product name: “SE2050”, average particle size: 0.5 μm)
(e-2) Methacrylic surface-treated nanosilica filler (manufactured by ADMATECHS COMPANY LIMITED, product name: “YA050C-SM”, average particle size: approximately 50 nm)
(e-3) Resin filler (manufactured by Rohm and Haas Japan KK, product name: “EXL-2655”, core-shell-type organic microparticles)

### Examples 1 to 3 and Comparative Examples 1 to 2

### <Production of Bonding Adhesive Layer>

An organic solvent (cyclohexanone) was added to the component (a), the component (b), the component (c), the component (d), and the component (e) at a mass ratio shown in Table 1 such that an NV value ([Mass of Varnish after Drying]/[Mass of Varnish before Drying]×100) was 60% by mass. After that, zirconia beads of $1.0 mm were added in the same mass as the total blending amount of the components (a) to (e) and the organic solvent, and were stirred with a ball mill (manufactured by Fritsch Japan Co., Ltd., a planetary fine pulverizer P-7) for 30 minutes. After stirring, the zirconia beads were removed by filtration to produce a coating varnish.

TABLE 1

| | | Blending amount |
|---|---|---|
| Component | Product name | (parts by mass) |
| (a-1) | EP1032H60 | 50 |
| (a-2) | YL983U | 20 |
| (b) | 2MAOK-PW | 6 |
| (c) | ZX1356 | 20 |
| (d) | Glutaric acid | 6 |
| (e-1) | SE2050 | 20 |
| (e-2) | YA050C-SM | 50 |
| (e-3) | EXL-2655 | 10 |

The obtained coating varnish was applied onto a base material film (manufactured by Toyobo Film Solutions Co., Ltd., product name: “PUREX A55”) with a small precision coater (manufactured by Yasui Seiki Company, Ltd.), and was dried at 100° C. for 5 minutes to form a bonding adhesive layer with a thickness of 20 μm.

### <Production of Backgrind Tape>

An acrylic copolymer using 2-ethyl hexyl acrylate and methyl methacrylate as a main monomer, and hydroxyethyl acrylate and an acrylic acid as a functional group monomer was obtained by a solution polymerization method. The weight average molecular weight of the synthesized acrylic copolymer was 400000, and the glass transition point was −38° C. 100 parts by mass of the acrylic copolymer were blended with 10 parts by mass of a polyfunctional isocyanate cross-linking agent (manufactured by Nippon Polyurethane Industry Co., Ltd., product name: “Coronate HL”) to prepare a varnish for a pressure-sensitive adhesive.

The varnish for a pressure-sensitive adhesive was applied onto a polyethylene terephthalate (PET) base material (manufactured by UNITIKA LTD., product name: “EMBLET S25”) with a thickness of 25 μm by using an applicator while adjusting a gap such that the thickness of a pressure-sensitive adhesive layer after drying was 20 μm, and was dried at 80° C. for 5 minutes. Accordingly, a backgrind tape was obtained in which the pressure-sensitive adhesive layer was formed on the base material.

### <Production of Adhesive Film for Semiconductor Wafer Processing>

Next, the backgrind tape was stuck onto the surface of the bonding adhesive layer on a side opposite to the base material film in a condition of 50° C., a line pressure of 3 kgf, and a rate of 5 m/minute to obtain an adhesive film for semiconductor wafer processing having a stacked structure of Base Material Film/Bonding Adhesive Layer/Pressure-Sensitive Adhesive Layer/Base Material.

In the obtained multilayer film, the backgrind tape and the bonding adhesive layer (a layer other than the base material film), as illustrated in FIG. 2, were precut to have a circular shape with a diameter (a precut diameter) shown in Table 2 in plan view to obtain an adhesive film for semiconductor wafer processing of Examples 1 to 3 and Comparative Examples 1 and 2, including the precut stacked body.

### [Evaluation of Chip and Crack on Semiconductor Wafer]

The stacked body was peeled from the adhesive film obtained in Examples and Comparative Examples, the bonding adhesive layer side of the stacked body was stuck onto the surface of a silicon wafer (a diameter of 300 mm, a thickness of 775 μm) by using a vacuum laminator (manufactured by Nikko-Materials Co., Ltd., product name: “V130”), in a condition of diaphragm temperature: 80° C., stage temperature: 40° C., pressure: 0.5 MPa, and pressurization time: 60 seconds.

The silicon wafer onto which the stacked body was stuck was ground on a side opposite to a side where the stacked body was stuck by using a backgrinder (manufactured by DISCO Inc., product name: “DGP8761”). The grinding was performed to a finish thickness Z1 shown in Table 2 by using grinding stone with a particle size of #340, and then, to a finish thickness Z2 shown in Table 2 by using grinding stone with a particle size of #6000.

After grinding, the surface of the wafer was observed with an optical microscope, and whether a chip and a crack with a size of 2 mm or more occurred on the end portion of the wafer was checked. A case where none of the chip and the crack with a size of 2 mm or more occurred was evaluated as “A”, and a case where at least one of the chip and the crack with a size of 2 mm or more occurred was evaluated as “B”. Results are shown in Table 2.

[Evaluation of Presence or Absence of Attachment of Bonding Adhesive Layer with Respect to Stage]

After grinding in the evaluation of the chip and the crack on the semiconductor wafer, the presence or absence of the attachment of the stacked body (the bonding adhesive layer) with respect to the stage of the backgrinder was visually checked. A case where there is no attachment of the bonding adhesive layer with respect to the stage was evaluated as “A”, and a case where there is the attachment of the bonding adhesive layer with respect to the stage was evaluated as “B”. Results are shown in Table 2.

TABLE 2

| | | | | | Attachment |
|---|---|---|---|---|---|
| | | | | Significant | of bonding |
| | Precut | | | chip and | adhesive layer |
| | diameter | Z1 | Z2 | crack on | with respect |
| | (mm) | (μm) | (μm) | wafer | to stage |
| Example 1 | 299.5 | 100 | 60 | A | A |
| Example 2 | 299.0 | 100 | 60 | A | A |
| Example 3 | 298.5 | 100 | 60 | A | A |
| Comparative | 300.0 | 100 | 60 | A | B |
| Example 1 | | | | | |
| Comparative | 298.0 | 100 | 60 | B | A |
| Example 2 | | | | | |

### REFERENCE SIGNS LIST

1: base material film, 2: bonding adhesive layer, 3: pressure-sensitive adhesive layer, 4: base material, 5: backgrind tape, 6: stacked body, 10: adhesive film for semiconductor wafer processing.

1. A method for manufacturing a semiconductor device, comprising:
preparing a semiconductor wafer including a plurality of electrodes on one of main surfaces to stick a stacked body, which includes a backgrind tape including a base material and a pressure-sensitive adhesive layer formed on the base material, and a bonding adhesive layer formed on the pressure-sensitive adhesive layer, onto the semiconductor wafer on a side in which the electrode is provided from the bonding adhesive layer side;
grinding the semiconductor wafer on a side opposite to the side in which the electrode is provided to make the semiconductor wafer thin;
dicing the thinned semiconductor wafer and the bonding adhesive layer to be singulated into a semiconductor chip with the bonding adhesive layer; and
electrically connecting an electrode of the semiconductor chip with the bonding adhesive layer to an electrode of another semiconductor chip or a wiring circuit board,
wherein the semiconductor wafer and the stacked body have a circular shape in plan view, and
in plan view, a diameter A of the semiconductor wafer and a diameter X of the stacked body satisfy a relationship of Expression (1) described below:
$$A - 1.5 mm \leq X < A . \qquad ( 1 )$$

2. The method for manufacturing a semiconductor device according to claim 1,
wherein a bonding adhesive force between the pressure-sensitive adhesive layer and the bonding adhesive layer is lower than a bonding adhesive force between the bonding adhesive layer and the semiconductor wafer.

3. An adhesive film for semiconductor wafer processing, comprising
a stacked body, which includes a backgrind tape including a base material and a pressure-sensitive adhesive layer formed on the base material, and a bonding adhesive layer formed on the pressure-sensitive adhesive layer,
wherein the semiconductor wafer and the stacked body have a circular shape in plan view, and
in plan view, a diameter A of the semiconductor wafer and a diameter X of the stacked body satisfy a relationship of Expression (1) described below:
$$A - 1.5 mm \leq X < A . \qquad ( 1 )$$
